(19) United States
(12) Patent Application Publication
(10) Pub. No.: US 2007/0148847 A1
(43) Pub. Date: Jun. 28, 2007

(54) Method of Fabricating CMOS Image Sensor

(76) Inventor: Chang Hun Han, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/613,218

(22) Filed: Dec. 20, 2006

(30) Foreign Application Priority Data
Dec. 28, 2005 (KR) 10-2005-0132365

(51) Int. Cl. H01L 21/8238

(52) U.S. Cl. 438/199

(57) ABSTRACT

A method of fabricating a CMOS image sensor is provided. According to an embodiment, a device isolation layer is formed in a semiconductor substrate to define a device isolation region and an active region. A gate insulating layer and a polysilicon layer are formed on the semiconductor substrate. Impurity ions are implanted at high concentration into the polysilicon layer. Then, the polysilicon layer and the gate insulating layer are selectively removed to form a gate electrode. Impurity ions are implanted into the active region to form a photodiode region. Impurity ions are implanted into the active region to form source/drain

### RELATED APPLICATION(S)

This application claims priority under 35 U.S.C. §119(e) of Korean Patent Application No. 10-2005-0132365 filed Dec. 28, 2005, which is incorporated herein by reference in its entirety.

### FIELD OF THE INVENTION

The present invention relates to a method of fabricating a CMOS image sensor.

### BACKGROUND OF THE INVENTION

An image sensor is a semiconductor device that converts an optical image into an electrical signal. The image sensor is mainly classified as a charge coupled device (CCD) or a complementary metal oxide semiconductor (CMOS) image sensor. In the CCD, electron carriers are stored and transferred in adjacent metal-oxide-silicon (MOS) capacitors.

The CMOS image sensor employs a switching mode by forming MOS transistors for each unit pixel using CMOS technology, and using a control circuit and a signal processing circuit as peripheral circuits in conjunction with the MOS transistors to sequentially detect outputs of photodiodes

The CCD has several disadvantages such as a complicated driving system, high power consumption, and a complicated process due to the plurality of mask processes. In addition, since the signal processing circuit cannot be formed on the CCD chip, it is difficult to fabricate a one-chip CCD. Therefore, research has been recently conducted into developing a CMOS image sensor using a sub-micron CMOS technology to address such disadvantages.

The CMOS image sensor displays an image by sequentially detecting signals through the switching mode, wherein the unit pixel is configured with a photodiode and the MOS transistors.

Since the CMOS image sensor is fabricated using CMOS technology, the CMOS image sensor has advantages such as low power consumption and a simple fabrication process using approximately 20 masks as compared to the CCD process requiring 30-40 masks. In addition, it is possible to fabricate a plurality of signal processing circuits on a single chip. In this respect, the CMOS image sensor has been in the limelight as a next generation image sensor, and is being used in various applications such as a digital still camera (DSC), a personal computer (PC) camera, and a mobile camera.

The CMOS image sensor is classified as a 3T type, a 4T type, or 5T type according to the number of the transistors formed in a unit pixel. The 3T type CMOS image sensor is configured with one photodiode and three transistors, and the 4T type CMOS image sensor is configured with one photodiode and four transistors. A unit cell of the 3T type CMOS image sensor is discussed below with reference to FIGS. 1-3.

FIG. 1 is an equivalent circuit diagram of a related art 3T type CMOS image sensor.

Referring to FIG. 1, a unit pixel of the 3T type CMOS image sensor includes a photodiode PD and three NMOS transistors (T1, T2, and T3). A cathode of the photodiode PD is connected to the drain of the first NMOS transistor (T1) and the gate of the second NMOS transistor (T2).

Sources of the first and second NMOS transistors (T1 and T2) are connected to a power line for supplying a reference voltage VR, and the gate of the first NMOS transistor (T1) is connected to a reset line for supplying a reset signal RST.

The source of the third NMOS transistor (T3) is connected to the drain of the second NMOS transistor (T2), the drain of the third NMOS transistor (T3) is connected to a reading circuit through a signal line, and the gate of the third NMOS transistor (T3) is connected to a column select line for supplying a select signal SLCT.

Therefore, the first NMOS transistor (T1) is referred to as a reset transistor Rx, the second NMOS transistor (T2) is referred to as a drive transistor Dx, and the third NMOS transistor (T3) is referred to as a select transistor Sx.

FIG. 2 is a layout illustrating a unit cell of a related art 3T type CMOS image sensor.

Referring to FIG. 2, in an active region 10 defined in a semiconductor substrate, a photodiode region 20 is formed on the wide portion of the active region 10, and gate electrodes 30, 40 and 50 of the three transistors are formed to respectively overlap the other portions of the active region 10.

That is, a reset transistor Rx, a drive transistor Dx, and a select transistor Sx are formed by the gate electrodes 30, 40 and 50, respectively.

Here, impurity ions are implanted into the active region 10 of each transistor except for portions of the active region under the gate electrodes 30, 40 and 50 to form source/drain regions of each transistor.

A power voltage Vdd is applied to the source/drain regions between the reset transistor Rx and the drive transistor Dx, and the source/drain regions at one end of the select transistor Sx are connected to the reading circuit.

Although not shown, each of the gate electrodes 30, 40 and 50 are connected to a signal line, which has a pad at one end and is connected to an external driver circuit.

FIG. 3 is a view showing impurity-implanted regions in a related art CMOS image sensor.

Referring to FIG. 3, a high concentration n+ type diffusion region 70 is formed by implanting N type impurity ions at concentration of 1E15 or higher into the gate electrodes 30, 40 and 50 and the active region 10 except for the photodiode region 20.

High concentration n+ type impurity ions are also implanted into a portion of the photodiode region 20 to form an ohmic resistor for forming a contact. However, some of the impurity ions may be implanted into the photodiode region 20 due to a mask misalignment while the high concentration n+ type impurity ions are being implanted into the gate electrode 30.

FIGS. 4A to 4E are cross-sectional views illustrating a method of fabricating a related art CMOS image sensor.

Referring to FIG. 4A, an epitaxial process is performed to form a low concentration P− type epitaxial layer 62 on a high concentration P⁺⁺ type semiconductor substrate 61.

Subsequently, an active region and a device isolation region are defined in the semiconductor substrate 61, and a device isolation layer 63 is formed in the device isolation region through shallow trench isolation (STI) or local oxidation of silicon (LOCOS).

A gate insulating layer 64 and a conductive layer, e.g., a high concentration polysilicon layer, are sequentially deposited on an entire surface of the epitaxial layer 62 where the device isolation layer 63 is formed. Thereafter, the conductive layer and the gate insulating layer 64 are selectively removed to form a gate electrode 65.

Referring to FIG. 4B, a first photoresist layer 66 is applied on an entire surface of the semiconductor substrate 61, and then patterned to expose blue, green, and red photodiode regions 67 by exposure and development processes.

Next, low concentration n⁻ type impurity ions are implanted into the epitaxial layer 62 using the patterned first photoresist layer 66 as a mask to form a low concentration n⁻ type diffusion region in the blue, green, red photodiode regions 67.

Each photodiode region 67 is a source region of the reset transistor Rx (refer to FIGS. 1 and 2).

Meanwhile, when a reverse bias is applied between the photodiode region 67 and the low concentration p⁻ type epitaxial layer 62, a depletion layer is created, and electrons generated by light incident thereon decrease the potential of the drive transistor when the reset transistor is turned off. In such a manner, the potential keeps decreasing after the reset transistor is turned on and then turned off, generating a voltage difference. The image sensor operates using the voltage difference for signal processing.

The photodiode regions 67 are formed to the same depth of 2-3 μm.

That is, the photodiode regions 67 are formed to the same depth by implanting impurity ions using the same ion implantation energy.

Referring to FIG. 4C, the first photoresist layer 66 is completely removed, and an insulating layer is then deposited on an entire surface of the semiconductor substrate 61. Thereafter, an etch-back process is performed to form sidewall insulating layers 68 on both sides of the gate electrode 65.

Subsequently, a second photoresist layer 69 is applied on an entire surface of the semiconductor substrate 61, and then patterned so as to cover the photodiode regions 67 and expose the source/drain regions and the gate electrode 65 of each transistor by exposure and development processes.

Next, high concentration n⁺ type impurity ions are implanted into the exposed source/drain regions and gate electrode 65 using the patterned second photoresist layer 69 as a mask to form an n⁺ type diffusion region 70.

The CMOS image sensor incorporates developments in high integration technology. However, reducing the size of a pixel decreases the photosensitivity of the CMOS image sensor and is a great problem in a CMOS image sensor of one million or more pixels.

In order to dope the gates of the reset transistor, the drive transistor, and the select transistor with n type impurities to form a dual gate poly, it is necessary to dope the poly gates to the maximum concentration, which is mainly accomplished during the source/drain ion implantation.

Referring to FIG. 4D, the second photoresist layer 69 is removed. Thereafter, a third photoresist layer 71 is applied on an entire surface of the semiconductor substrate 61, and then patterned so as to expose the photodiode region 67 through exposure and development processes.

Subsequently, p⁰ type impurity ions are implanted into the photodiode region 67 where the n⁻ type diffusion region is formed using the patterned third photoresist layer 71 as a mask to form a p⁰ type diffusion region 72 beneath the surface of the semiconductor substrate 61.

Here, the p⁰ type diffusion region 72 is formed to a depth less than 0.1 μm.

Referring to FIG. 4E, the third photoresist layer 71 is removed, and then a heat treatment is performed on the semiconductor substrate 61 to diffuse the impurity diffusion regions.

However, during the ion implantation for the gate electrodes and source/drain regions, high concentration n+ type impurity ions may be implanted in the photodiode region due to a misalignment of a mask. This decreases the collection of charges in a photodiode, lowering the photosensitivity of the image sensor.

Furthermore, the misalignment of a mask generated for implanting high concentration impurity ions into the gate electrode and the source/drain regions of the reset transistor may lead to a misalignment in top and bottom, and right and left, which decreases the uniformity of the pixels.

### BRIEF SUMMARY

Accordingly, embodiments of the present invention are directed to a method of fabricating a CMOS image sensor that substantially obviates one or more problems due to limitations and/or disadvantages of the related art.

An object of embodiments of the present invention is to provide a method of fabricating a CMOS image sensor capable of preventing high concentration impurity ions from being implanted into a photodiode caused by misalignment of a mask.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of fabricating a complementary metal oxide semiconductor image sensor, the method including: forming a device isolation layer in a semiconductor substrate to define a device isolation region and an active region; forming a gate insulating layer and a polysilicon layer on the semiconductor substrate; implanting high concentration impurity ions into the polysilicon layer; selectively removing the polysilicon layer and the gate insulating layer to form a gate electrode; implanting impurity ions into one portion of the active region to form a photodiode; and implanting impurity ions into another portion of the active region to form source/drain regions.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is an equivalent circuit diagram of a related art 3T type CMOS image sensor;

FIG. 2 is a layout illustrating a unit cell of a related art 3T type CMOS image sensor;

FIG. 3 is a layout view illustrating impurity regions of a related art CMOS image sensor;

FIGS. 4A to 4E are cross-sectional views illustrating a method of fabricating a related art CMOS image sensor; and

FIGS. 5A to 5H are cross-sectional views illustrating a method of fabricating a CMOS image sensor according to an embodiment of the present invention.

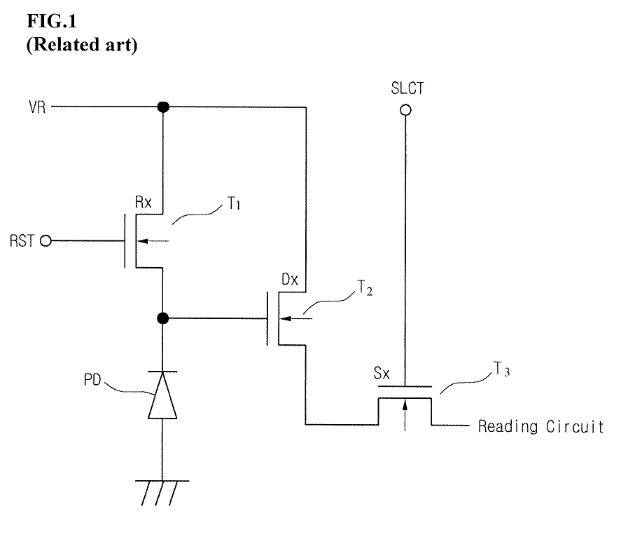

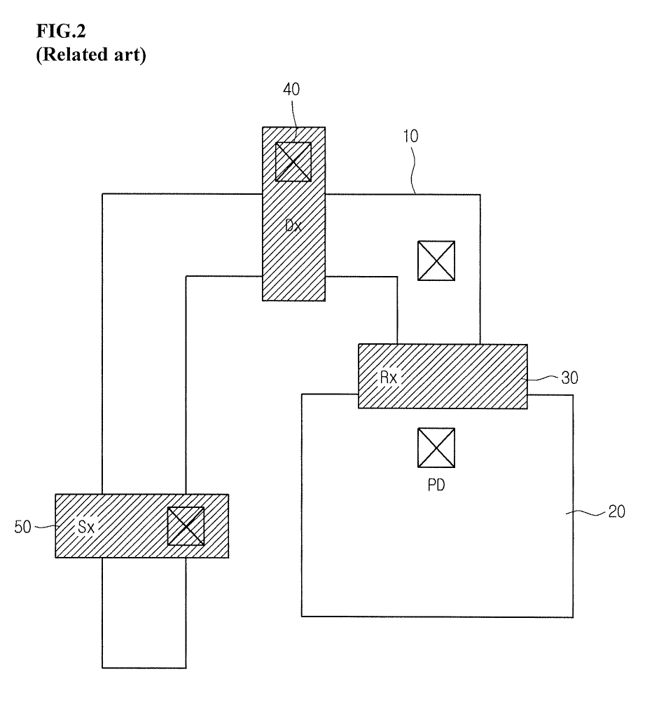

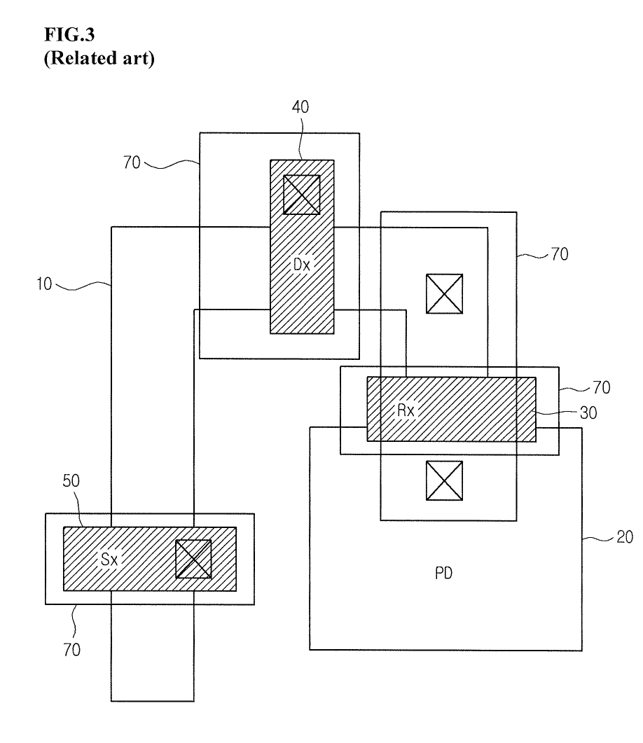

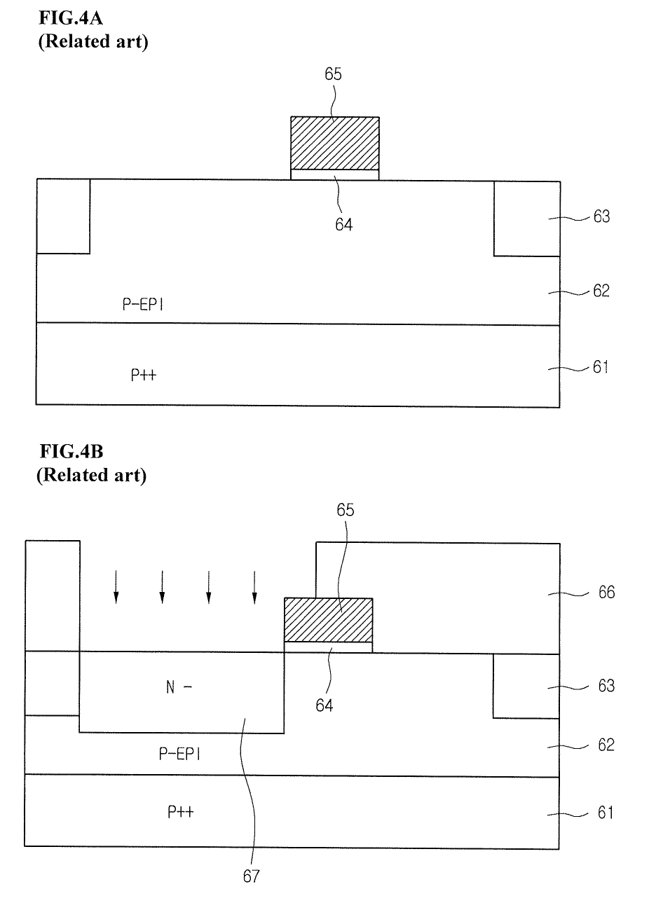

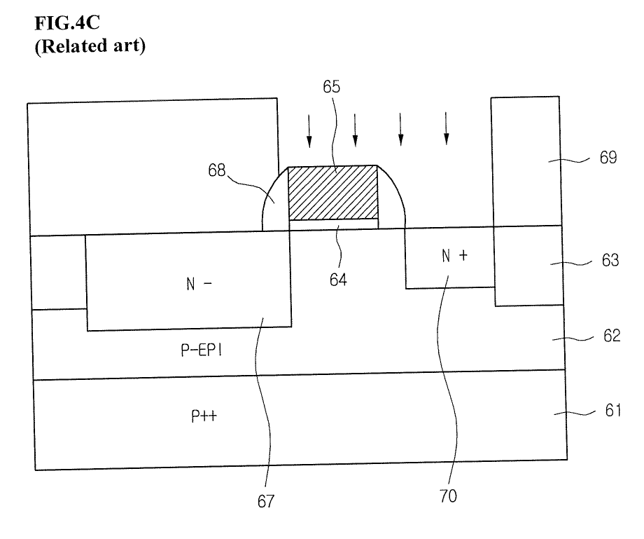

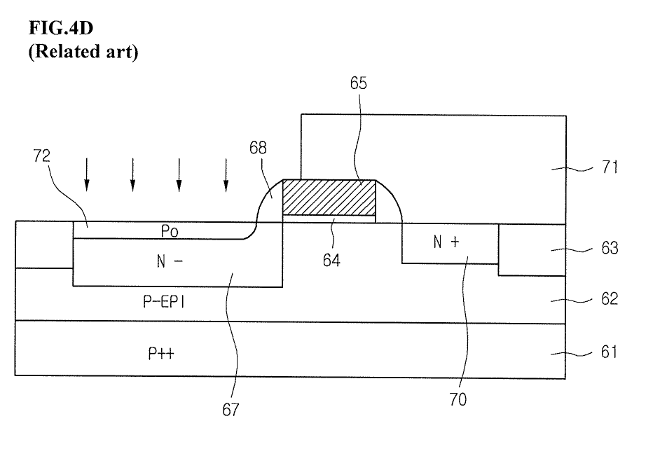

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

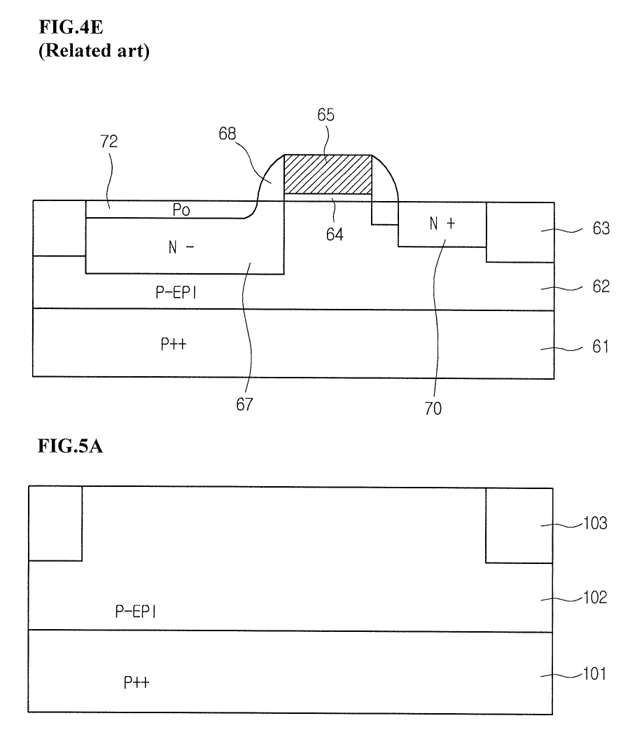

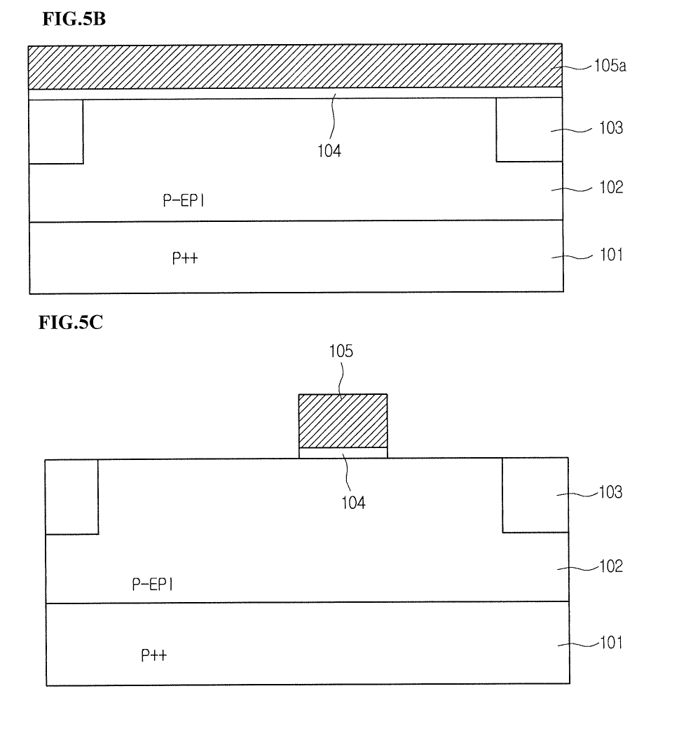

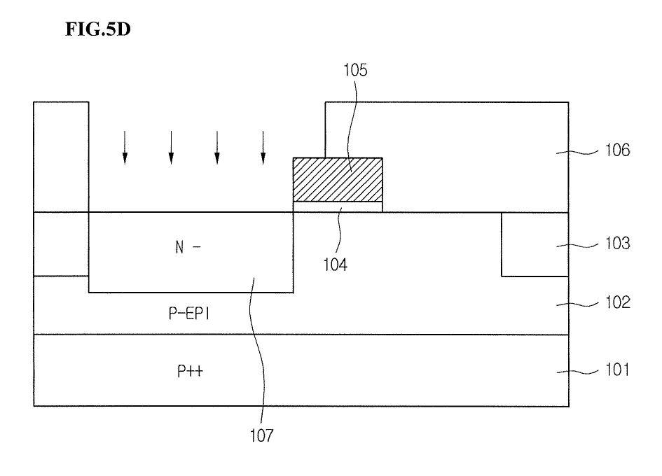

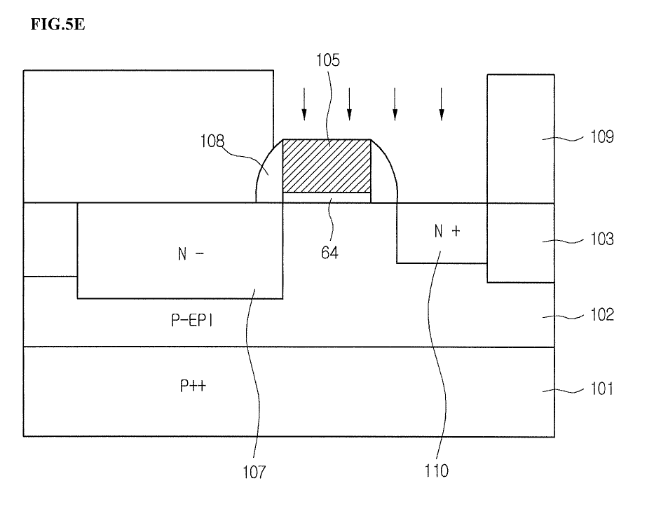

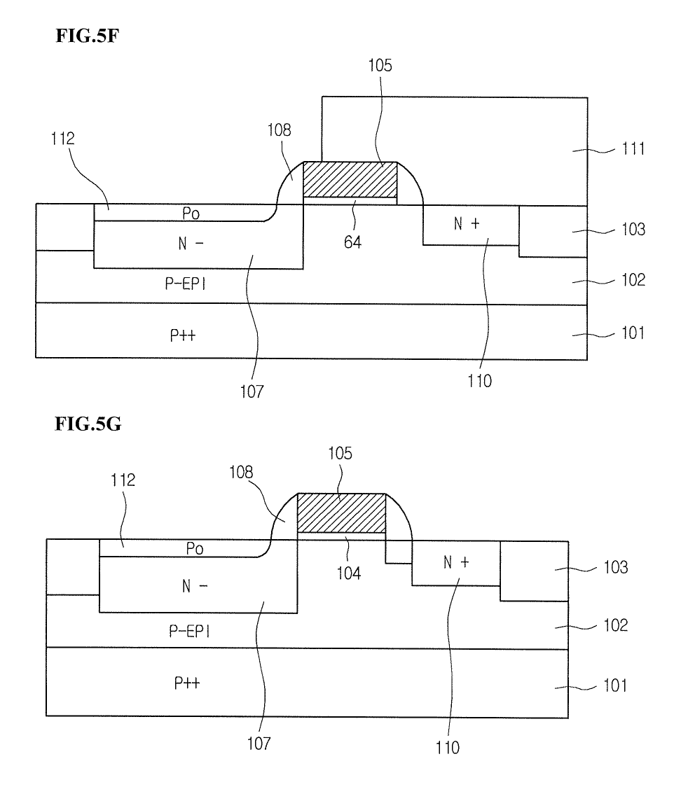

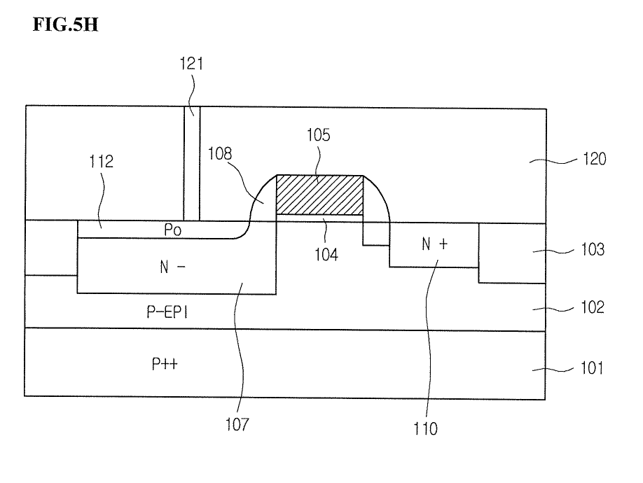

FIGS. 5A to 5H are cross-sectional views illustrating a method of fabricating a CMOS image sensor according to an embodiment of the present invention.

Referring to FIG. 5A, an epitaxial process can be performed to form a low concentration first conductive type (p⁻ type) epitaxial layer 102 on a semiconductor substrate 101. The semiconductor substrate 101 can be a high concentration first conductive type (P++ type) single crystal silicon substrate.

A depletion region for a photodiode can be formed large and deep in the low concentration first conductive type epitaxial layer 102, which increases the capability of a low voltage photodiode to collect photocharges and improves the photosensitivity of the image sensor.

In another embodiment, a p type epitaxial layer may be formed on an n type semiconductor substrate. The low concentration first conductive type epitaxial layer 102 can be formed to a depth of 4-7 μm.

Subsequently, a device isolation layer 103 can be formed in the semiconductor substrate 101 to isolate devices from each other.

A method of forming the device isolation layer 103 will now be described.

A pad oxide layer, a pad nitride layer, and a tetra ethyl ortho silicate (TEOS) oxide layer can be sequentially formed on the semiconductor substrate 101, and a photoresist layer can be formed on the TEOS oxide layer.

The photoresist layer can be patterned using a mask defining an active region and a device isolation region through exposure and development processes to remove the photoresist layer on the device isolation region.

The pad oxide layer, the pad nitride layer, and the TEOS oxide layer on the device isolation region can be selectively removed using the patterned photoresist layer as a mask.

A portion of the semiconductor substrate 101 corresponding to the device isolation region can be etched to a predetermined depth so as to form a trench, using the patterned pad oxide layer, pad nitride layer, and TEOS oxide layer as a mask. Thereafter, the photoresist layer can be completely removed.

A thin sacrificial oxide layer can be formed on an entire surface of the semiconductor substrate 101 where the trench is formed, and then an O₃ TEOS layer can be formed on the semiconductor substrate 101 so as to fill the trench. The sacrificial oxide layer can be formed even on an inner wall of the trench, and the O₃ TEOS layer can be formed at a temperature of approximately 1000° C. or higher.

The O₃ TEOS layer can be removed from the substrate except for the portion of the O₃ TEOS layer on the trench region using a chemical mechanical polishing (CMP) process to form the device isolation layer 103 within the trench. Thereafter, the pad oxide layer, the pad nitride layer, and the TEOS oxide layer can be removed.

Referring to FIG. 5B, a gate insulating layer 104 and a polysilicon layer 105a can be formed on an entire surface of the semiconductor substrate 101.

The gate insulating layer 104 may be formed by thermal oxidation or chemical vapor deposition (CVD).

Next, high concentration n type impurity ions can be implanted into the polysilicon layer 105a.

Referring to FIG. 5C, the ion implanted polysilicon layer 105a and the gate insulating layer 104 can be selectively removed to form a gate electrode 105 by photolithography and etching processes.

Referring to FIG. 5D, a first photoresist layer 106 can be applied on an entire surface of the semiconductor substrate 101 including the gate electrode 105, and then selectively patterned so as to expose each photodiode region by exposure and development processes.

Next, low concentration second conductive type (n⁻ type) impurity ions can be implanted into the epitaxial layer 102 using the patterned first photoresist layer 106 as a mask to form an n⁻ type diffusion region 107 in the photodiode region.

Referring to FIG. 5E, the first photoresist layer 106 can be removed, and an insulating layer can be formed on an entire surface of the semiconductor substrate 101 including the gate electrode 105. Then, an etch-back process can be performed to form insulating layer sidewalls 108 on both sides of the gate electrode 105.

Subsequently, a second photoresist layer 109 can be applied on an entire surface of the semiconductor substrate 101 including the gate electrode 105, and then patterned so as to cover the photodiode regions and expose source/drain regions of the each transistor (floating diffusion region) by exposure and development processes.

Next, high concentration second conductive type (n⁺ type) impurity ions can be implanted into the exposed source/drain regions using the patterned second photoresist layer 109 as a mask to form an n⁺ type diffusion region (floating diffusion region) 110.

Referring to FIG. 5F, the second photoresist layer 109 removed, and a third photoresist layer 111 can be applied on an entire surface of the semiconductor substrate 101. The second photoresist layer 111 can then be patterned so as to expose a portion of each photodiode region by exposure and development processes.

Subsequently, first conductive type (p⁰ type) impurity ions can be implanted into the epitaxial layer 102 where the n⁻ type diffusion region 107 is formed, using the patterned third photoresist layer 111 as a mask, to form a p⁰ type diffusion region 112 beneath a surface of the epitaxial layer 102.

Referring to FIG. 5G, the third photoresist layer 111 can be removed, and a heat treatment can be performed on the semiconductor substrate 101 to diffuse the impurity diffusion regions.

Referring to FIG. 5H, an interlayer insulating layer 120 can be formed on an entire surface of the semiconductor substrate 101. Then, a portion of the interlayer insulating layer 120 can be removed to form a contact 121 so as connect with the p⁰ type diffusion region 112.

Next, ions can be implanted at high concentration into the contact 121. Because ions can be implanted after forming the contact 121, an ohmic resistor contact can be formed using a minimum ion implantation.

In subsequent processes, a metal wiring can be formed, and a color filter layer and microlenses can be formed to complete the image sensor.

A 3T type CMOS image sensor is illustrated in the described embodiments of the present invention, but the present invention is not limited thereto, and can be applied for example, to a 4T type CMOS image sensor in the same manner.

As described above, a method of fabricating a CMOS image sensor according to embodiments of the present invention can have the following effects.

The doping of a reset transistor at high concentrations in a 3T type pixel array can be accomplished while preventing ions from being implanted into the photodiode, thereby solving the decrease in capacitance and improving the uniformity of pixels using self-alignment ion implantation.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method of fabricating a complementary metal oxide semiconductor image sensor, the method comprising:
forming a device isolation layer in a semiconductor substrate to define a device isolation region and an active region;
forming a gate insulating layer and a polysilicon layer on the semiconductor substrate;
implanting impurity ions at high concentration into the polysilicon layer;
selectively removing the ion implanted polysilicon layer and the gate insulating layer to form a gate electrode;
implanting impurity ions into one portion of the active region to form a photodiode region; and
implanting impurity ions into another portion of the active region to form source/drain regions.

2. The method according to claim 1, further comprising forming an insulating layer sidewall at both sides of the gate electrode.

3. The method according to claim 1, wherein the gate insulating layer is formed by thermal oxidation or chemical vapor deposition.

4. The method according to claim 1, wherein the polysilicon layer is implanted with n type impurity ions at high concentration.

5. The method according to claim 1, further comprising forming an interlayer insulating layer on an entire surface of the semiconductor substrate and forming a contact to the photodiode region penetrating the interlayer insulating layer.

6. The method according to claim 5, further comprising implanting impurity ions into the contact.
